(19) United States
(12) Patent Application Publication
(10) Pub. No.: US 2016/0146913 A1
(43) Pub. Date: May 26, 2016

(54) PHASE MONITORING FOR MULTICHANNEL MR TRANSMISSION SYSTEMS

(71) Applicants: Wolfgang Renz, Erlangen (DE); Karsten Wicklow, Bamberg (DE)

(72) Inventors: Wolfgang Renz, Erlangen (DE); Karsten Wicklow, Bamberg (DE)

(21) Appl. No.: 14/935,564

(22) Filed: Nov. 9, 2015

(30) Foreign Application Priority Data
Nov. 24, 2014 (DE) 102014223878.1

(51) Int. Cl. G01R 33/483; G01R 33/54; G01R 33/36

(52) U.S. Cl. CPC G01R 33/483; G01R 33/3642; G01R 33/543

(57) ABSTRACT

A magnetic resonance tomography system is provided having a multichannel transmission system for generating signals to be transmitted for multiple transmit channels. The system includes devices for decoupling signals of different transmit channels from a transmit chain and applying signals decoupled from the transmit chain at inputs of a Butler matrix. The system includes a Butler matrix configured such that a combination of signals of different transmit channels applied at its inputs occurs such that the amplitude of Butler matrix output signals at outputs of the Butler matrix is a function of the relative phases that the phases of signals of different transmit channels have relative to each other at inputs of the Butler matrix. The Butler matrix output signals are applied at inputs of a monitoring unit configured to determine the relative phases of the signals on a basis of amplitudes of the Butler matrix output signals.

This application claims the benefit of DE 10 2014 223 878.1, filed on Nov. 24, 2014, which is hereby incorporated by reference in its entirety.

### TECHNICAL FIELD

The embodiments relate to methods for measuring relative phases of signals of different transmit channels of a magnetic resonance tomography system.

### BACKGROUND

A Butler matrix is known, for example, from Butler J. et al., “Beamforming matrix simplifies design of electronically scanned antennas, Electron. Design, vol. 9, pp. 170-173, April 1961; J. Nistler et al., “Using a Mode Concept to Reduce Hardware Needs for Multi Channel Transmit Arrays,” Proc. Intl. Soc. Mag. Reson. Med. 14 (2006); and Henrik Nord, “Implementation of a 8×8-Butler Matrix in Microstrip,” Technische Universitat Wien Diploma Thesis Royal Institute of Technology Stockholm, TRITA-TET-EX-97-4.

### BRIEF SUMMARY

The scope of the present invention is defined solely by the appended claims and is not affected to any degree by the statements within this summary. The present embodiments may obviate one or more of the drawbacks or limitations in the related art.

It is an object to optimize a phase monitoring arrangement for multichannel MR transmission systems.

### BRIEF DESCRIPTION OF THE DRAWINGS

Further features and advantages of possible embodiments will emerge from the description which follows of exemplary embodiments with reference to the drawing, in which:

FIG. 1 schematically depicts in a block diagram an example of a phase monitoring arrangement for multichannel MR transmission systems with a Butler matrix.

FIG. 2 depicts an example of a known Butler matrix.

FIG. 3 schematically depicts an example of a MRT system.

### DETAILED DESCRIPTION

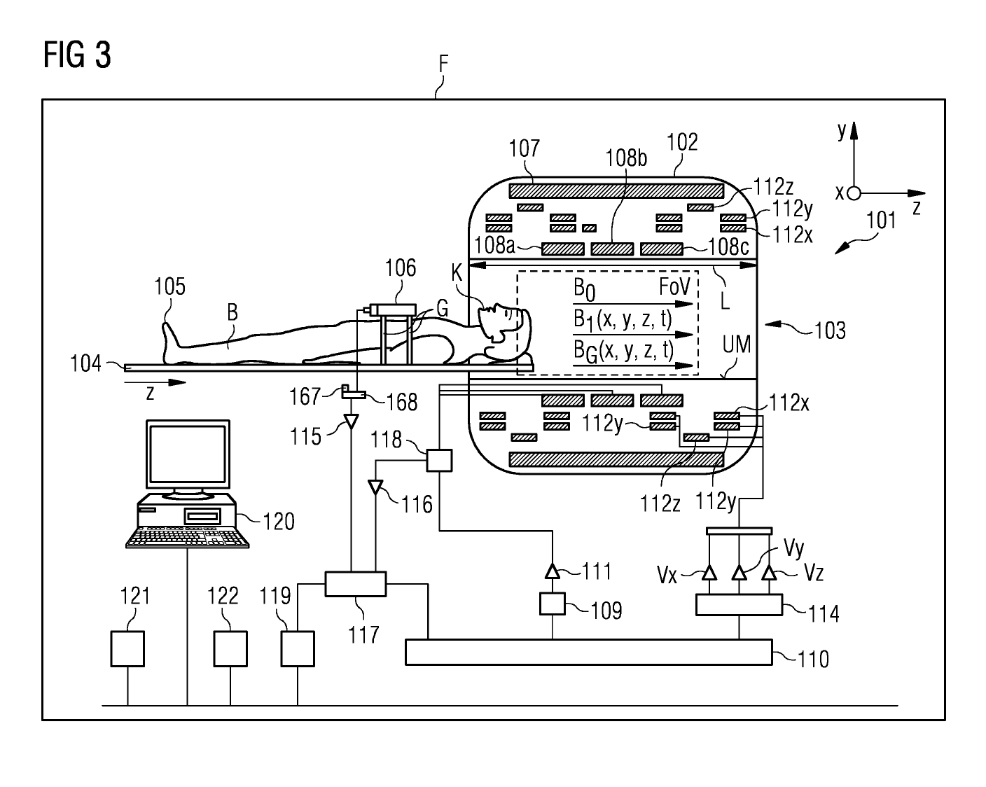

FIG. 3 depicts (including, also in particular, for the technical background) an imaging magnetic resonance device MRT 101 (contained in a shielded room or Faraday cage F) including a hollow cylinder 102 having a tubular bore 103 into which a patient couch 104 bearing a body 105 (e.g., an examination object or patient) (with or without local coil arrangement 106) may be introduced in the direction of the arrow z so that images of the patient 105 may be generated by an imaging method. Disposed on the patient 105 here is a local coil arrangement 106, which may be used in a local region (also referred to as field of view or FOV) of the MRT to generate images of a subregion of the body 105 in the FOV. Signals of the local coil arrangement 106 may be evaluated (e.g., converted into images, stored, or displayed) by an evaluation device (168, 115, 117, 119, 120, 121, etc.) of the MRT 101 that may be connected to the local coil arrangement 106, e.g., via coaxial cable or wirelessly (167), etc.

When a magnetic resonance device MRT 101 is used in order to examine a body 105 (e.g., an examination object or a patient) by magnetic resonance imaging, different magnetic fields that are coordinated with one another with the utmost precision in terms of their temporal and spatial characteristics are radiated onto the body 105. A strong magnet (e.g., a cryomagnet 107) in a measurement chamber having an in this case tunnel-shaped bore 103 generates a strong static main magnetic field B₀ ranging, e.g., from 0.2 Tesla to 3 Tesla or more. A body 105 that is to be examined, supported on a patient couch 104, is moved into a region of the main magnetic field B₀ that is approximately homogeneous in the area of observation FoV (“Field of View”). The nuclear spins of atomic nuclei of the body 105 are excited by way of magnetic radio-frequency excitation pulses B1(x, y, z, t) emitted via a radio-frequency antenna (and/or a local coil arrangement, if necessary) depicted here as a body coil 108 (e.g., multipart=108a, 108b, 108c). Radio-frequency excitation pulses are generated, e.g., by a pulse generation unit 109 controlled by a pulse sequence control unit 110. Following amplification by a radio-frequency amplifier 111, the pulses are directed to the radio-frequency antenna 108. The radio-frequency system depicted here is indicated only schematically. More than one pulse generation unit 109, more than one radio-frequency amplifier 111, and a plurality of radio-frequency antennas 108a, b, c are used in a magnetic resonance device 101.

The magnetic resonance device 101 also has gradient coils 112x, 112y, 112z by which magnetic gradient fields BG(x, y, z, t) are radiated in the course of a measurement in order to provoke selective layer excitation and for spatial encoding of the measurement signal. The gradient coils 112x, 112y, 112z are controlled by a gradient coil control unit 114 (and, if appropriate, by way of amplifiers Vx, Vy, Vz) which, like the pulse generation unit 109, is connected to the pulse sequence control unit 110.

Signals (RF1, RF2, RF3, RFn) emitted by the excited nuclear spins (of the atomic nuclei in the examination object) are received by the body coil 108a, b, c and/or at least one local coil arrangement 106, amplified by assigned radio-frequency preamplifiers 116 and further processed and digitized by a receive unit 117. The recorded measurement data is digitized and stored in the form of complex numeric values in a k-space matrix. An associated MR image may be reconstructed from the value-filled k-space matrix by a multidimensional Fourier transform.

For a coil that may be operated in both transmit and receive mode, (for example, the body coil 108 or a local coil 106), correct signal forwarding is regulated by an upstream duplexer 118.

From the measurement data, an image processing unit 119 generates an image displayed to a user via an operator console 120 and/or stored in a memory unit 121. A central computer unit 122 controls the individual system components.

In MR tomography as practiced today, images having a high signal-to-noise ratio (SNR) may be acquired by local coil arrangements (e.g., coils, local coils). These are antenna systems, which are positioned in direct proximity on (anterior), below (posterior), next to, or in the body 105. In the course of a MR measurement, the excited nuclei induce a voltage in the individual antennas of the local coil, which voltage is then amplified by a low-noise preamplifier (e.g., LNA, preamp) and forwarded to the receive electronics. So-called high-field systems (e.g., 1.5T-12T or more) are used to improve the signal-to-noise ratio, even with high-resolution images. If more individual antennas may be connected to a MR receive system than there are receivers present, a switching matrix (also referred to as RCCS), for example, is incorporated between receive antennas and receivers. The switching matrix routes the currently active receive channels (e.g., those currently lying in the magnet's field of view) to the receivers present. This enables more coil elements to be connected than there are receivers available, since in the case of whole-body coverage it is only necessary to read out those coils located in the FoV or, as the case may be, in the homogeneity volume of the magnet.

The term local coil arrangement 106 may refer to, e.g., an antenna system that may include, e.g., of one antenna element or of a plurality of antenna elements (e.g., coil elements) configured as an array coil. These individual antenna elements are embodied for example as loop antennas (e.g., loops), butterfly coils, flex coils, or saddle coils. A local coil arrangement includes, e.g., coil elements, a preamplifier, further electronics (e.g., standing wave traps, etc.), a housing, supports, and in certain cases a cable with plug-type connector by which the local coil arrangement is connected to the MRT system. A receiver 168 mounted on the MRT system side filters and digitizes a signal received by a local coil 106 and passes the data to a digital signal processing device, which may derive an image or a spectrum from the data acquired by a measurement and makes it available to the user, e.g., for subsequent diagnosis by him/her and/or for storage in a memory.

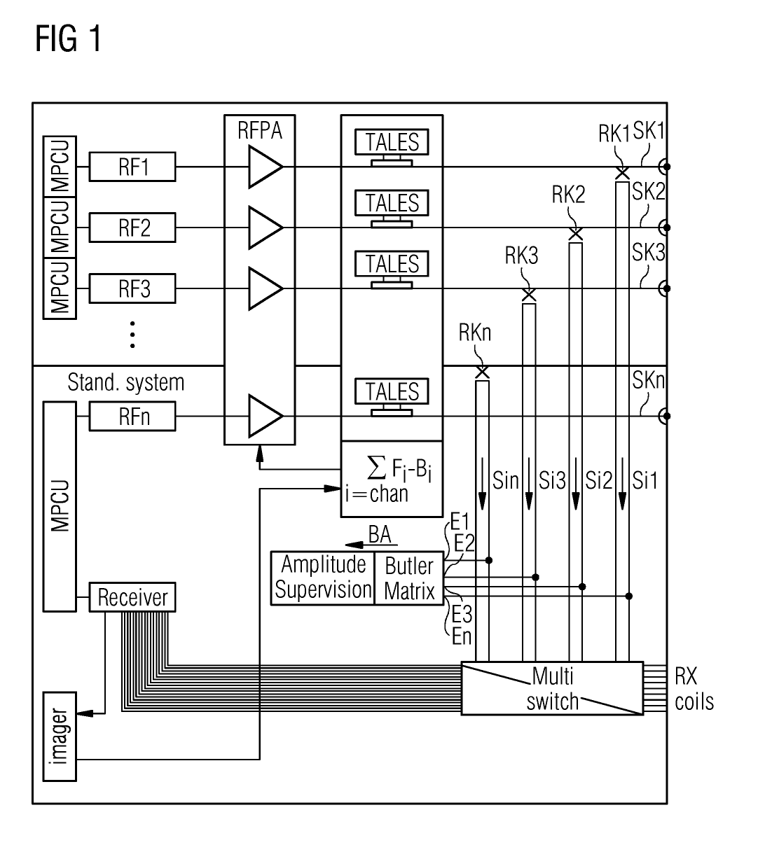

FIGS. 1-3 depict several details of example embodiments.

For the reliable and safe functioning of a multichannel transmission system the amplitude and phase fidelity of the (individual) signals (RF1, RF2, RF3, RFn) is of significance. In particular, the relative phases (e.g., as phase differences) of the (individual) signals (RF1, RF2, RF3, RFn) to each other (e.g., the phase difference of signals (RF1, RF2, RF3, RFn) to each other on different transmit paths) may be monitored continuously.

In certain examples, the phases of the individual channels are monitored through measured signals being decoupled from the individual transmit channels by directional couplers and then fed to the receivers of the MR system. The signals are here demodulated and evaluated with respect to the relative phases. The phase evaluation has to be recalibrated at each system start, and, during the measurement operation itself too, a regular check of the receive phase calibration is necessary.

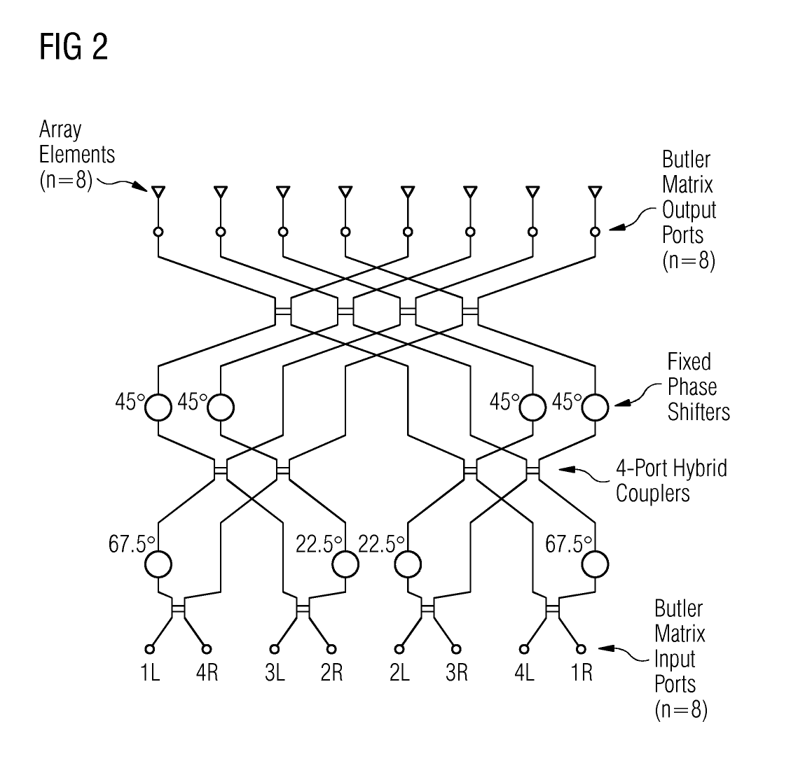

In accordance with embodiments, the phase monitoring is effected by a hardware solution. For this purpose, the signals (RF1, RF2, RF3, RFn) of the transmit chain are as hitherto decoupled, e.g., by directional couplers and then fed to a Butler matrix (e.g., as in the publication hereby fully incorporated by reference into the application: see Butler J. et al, “Beamforming matrix simplifies design of electronically scanned antennas,” Electron. Design, vol. 9, pp. 170-173, April 1961; and J. Nistler et al., “Using a Mode Concept to Reduce Hardware Needs for Multi Channel Transmit Arrays,” Proc. Intl. Soc. Mag. Reson. Med. 14 (2006)). A Butler matrix such as, e.g., in FIG. 2 is, e.g., also known from Henrik Nord, “Implementation of a 8×8-Butler Matrix in Microstrip,” Technische Universitat Wien Diploma Thesis Royal Institute of Technology Stockholm, TRITA -TET-EX-97-4, which is incorporated by reference into this application.

In FIG. 1, signals RF1, RF2, RF3, RFn to be transmitted by a multipart measurement, physiological, and communication unit (MPCU) on multiple transmit channels SK1, SK2, SK3, SKn and/or by multiple antenna elements (of coils 106, 108) by amplifiers of an amplification device (e.g., radio frequency power amplifier, RFPA) are amplified and supplied by an amplitude monitoring apparatus (e.g., transmit antenna level sensor, TALES) on transmit channels at the top right side of FIG. 1 to antenna elements of coils (106, 108).

Signals received by (e.g., also used for transmitting signals (RF1, RF2, RF3, RFn)) coils (106, 108=RX coils) are passed by a switching device (e.g., multiswitch, 118) to a receiver having, e.g., multiple amplifiers and passed from there to a measurement, physiological, and communication unit MPCU (as feedback) and to an imager device 117 for image generation.

In a Butler matrix referred to in FIG. 1 using the reference sign “Butler Matrix,” the signals applied at inputs (E1, E2, E3, En) of the Butler matrix are combined or connected, e.g., in such a way that Butler matrix output signals occur at the individual outputs of the Butler matrix only if signals with a precisely specified phase position and/or amplitude position relative to each other are applied at the inputs (E1, E2, E3, En) of the Butler matrix.

In particular, if signals with identical amplitude and phase are applied at all inputs (E1, E2, E3, En) of the Butler matrix, an output signal may occur, e.g., only at the output port (for what is known as Mode 0) and not then at all other outputs.

Phase monitoring may be performed, e.g., by a regular transmission of control pulses with identical amplitude and phase on all transmit channels (SK1, SK2, SK3, SKn) (also referred to as pTX channels) of the magnetic resonance tomography system and by amplitude monitoring of the output signals of the Butler matrix in a monitoring device (with the reference sign “Amplitude Supervision” in FIG. 1). By way of example, special detectors or also the system's receive channels may be used for this purpose. In the second scenario, a prior phase calibration of the receive channels is no longer necessary.

A further possible application of the proposed arrangement emerges for what is known as the compatibility mode.

Here, by setting identical amplitudes and a fixed phase position in conjunction with corresponding coils, a B₁ distribution is intended to be produced that is compatible with a CP field distribution (CP=circular polarized). Using the proposed arrangements and/or methods, this condition may be monitored continuously during the MRT imaging (measurement) as signals may then only occur at the output of the Butler matrix to which the CP phase distribution is assigned. To obtain the input signals for the Butler matrix, e.g., in addition to (directional coupler output) signals (RF1, RF2, RF3, RFn), signals directly from pickup probes in the respective coil are also possible at the coil plugs.

One advantage of the example embodiments may be to replace a relatively complex software solution for pTX phase monitoring, which is embedded deep in the system, with a largely autonomous and relatively simple hardware solution.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A magnetic resonance tomography system comprising:
a multichannel transmission system for generating signals to be transmitted for multiple transmit channels comprising:
devices for decoupling signals of different transmit channels from a transmit chain and applying signals decoupled from the transmit chain at inputs of a Butler matrix; and
the Butler matrix configured such that a combination of signals of different transmit channels applied at inputs of the Butler matrix occurs such that the amplitude of Butler matrix output signals that are output at outputs of the Butler matrix is a function of relative phases, the relative phases being phases of signals of different transmit channels relative to each other as phase differences at the inputs of the Butler matrix,
wherein the Butler matrix output signals are applied at inputs of a monitoring unit configured to determine or monitor the relative phases of the signals on a basis of amplitudes of the Butler matrix output signals.

2. The magnetic resonance tomography system as claimed in claim 1, further comprising:
directional couplers for decoupling signals of different transmit channels from the transmit chain and for applying signals decoupled from the transmit chain by way of directional couplers at the inputs of the Butler matrix.

3. The magnetic resonance tomography system as claimed in claim 2, wherein the devices for decoupling signals and for applying signals comprise at least one of the following: (1) detectors or pickup probes in coils configured to transmit and/or receive the signals, or (2) attenuator terminals at coil plugs on the coils configured to transmit and/or receive the signals.

4. The magnetic resonance tomography system as claimed in claim 3, wherein the amplitude of Butler matrix output signals is also a function of difference in amplitudes of signals of different transmit channels.

5. The magnetic resonance tomography system as claimed in claim 4, wherein phase monitoring a regular transmission of multiple control pulses with amplitude and phase defined to each other is provided respectively on at least two of a plurality of pTX channels or on all transmit channels applied via directional couplers at inputs of the Butler matrix, and wherein an amplitude monitoring of the output signals of the Butler matrix is provided.

6. The magnetic resonance tomography system as claimed in claim 5, wherein the system is configured, by setting identical amplitudes and a fixed phase position, to produce a B₁ distribution compatible with a field distribution.

7. The magnetic resonance tomography system as claimed in claim 1, wherein the devices for decoupling signals and for applying signals comprise at least one of the following: (1) detectors or pickup probes in coils configured to transmit and/or receive the signals, or (2) attenuator terminals at coil plugs on the coils configured to transmit and/or receive the signals.

8. The magnetic resonance tomography system as claimed in claim 7, wherein the amplitude of Butler matrix output signals is also a function of difference in amplitudes of signals of different transmit channels.

9. The magnetic resonance tomography system as claimed in claim 8, wherein phase monitoring a regular transmission of multiple control pulses with amplitude and phase defined to each other is provided respectively on at least two of a plurality of pTX channels or on all transmit channels applied via directional couplers at inputs of the Butler matrix, and wherein an amplitude monitoring of the output signals of the Butler matrix is provided.

10. The magnetic resonance tomography system as claimed in claim 9, wherein the system is configured, by setting identical amplitudes and a fixed phase position, to produce a B₁ distribution compatible with a field distribution.

11. The magnetic resonance tomography system as claimed in claim 1, wherein the amplitude of Butler matrix output signals is also a function of difference in amplitudes of signals of different transmit channels.

12. The magnetic resonance tomography system as claimed in claim 11, wherein phase monitoring a regular transmission of multiple control pulses with amplitude and phase defined to each other is provided respectively on at least two of a plurality of pTX channels or on all transmit channels applied via directional couplers at inputs of the Butler matrix, and wherein an amplitude monitoring of the output signals of the Butler matrix is provided.

13. The magnetic resonance tomography system as claimed in claim 12, wherein the system is configured, by setting identical amplitudes and a fixed phase position, to produce a B₁ distribution compatible with a field distribution.

14. The magnetic resonance tomography system as claimed in claim 1, wherein phase monitoring a regular transmission of multiple control pulses with amplitude and phase defined to each other is provided respectively on at least two of a plurality of pTX channels or on all transmit channels applied via directional couplers at inputs of the Butler matrix, and wherein an amplitude monitoring of the output signals of the Butler matrix is provided.

15. The magnetic resonance tomography system as claimed in claim 14, wherein the system is configured, by setting identical amplitudes and a fixed phase position, to produce a B₁ distribution compatible with a field distribution.

16. The magnetic resonance tomography system as claimed in claim 1, wherein the system is configured, by setting identical amplitudes and a fixed phase position, to produce a B₁ distribution compatible with a field distribution.

17. A method for measuring relative phases of signals of different transmit channels of a magnetic resonance tomography system, the method comprising:
measuring relative phases with decoupled signals being applied at a Butler matrix, the relative phases being phases of signals of different transmit channels of the magnetic resonance tomography system as phase differences relative to each other;
performing, by the Butler matrix, a combination of signals of different transmit channels applied at inputs of the Butler matrix such that the amplitude of Butler matrix output signals that are output at outputs of the Butler matrix is a function of the relative phases at the input of the Butler matrix;
applying the Butler matrix output signals at inputs of a monitoring unit; and
determining, at the monitoring unit, the relative phases on a basis of amplitudes of the Butler matrix output signals.
